(19) United States
(12) Patent Application Publication
(10) Pub. No.: US 2026/0190385 A1
(43) Pub. Date: Jul. 2, 2026

(54) SEMICONDUCTOR DEVICE

(71) Applicant: FUJI ELECTRIC CO., LTD., Kawasaki-shi (JP)

(72) Inventor: Chansoon KOO, Matsumoto-city (JP)

(73) Assignee: FUJI ELECTRIC CO., LTD., Kawasaki-shi (JP)

(21) Appl. No.: 19/373,320

(22) Filed: Oct. 29, 2025

(30) Foreign Application Priority Data
Dec. 26, 2024 (JP) 2024-230825

(51) Int. Cl. H10D 30/66; H10D 62/10; H10D 62/60; H10D 62/832

(52) U.S. Cl. CPC H10D 30/665; H10D 30/668; H10D 62/102; H10D 62/126; H10D 62/60; H10D 62/8325

(57) ABSTRACT

A semiconductor device having a termination structure portion surrounding an active region. The semiconductor device includes: a semiconductor substrate; a first semiconductor layer provided on the semiconductor substrate; a parallel pn structure provided in the first semiconductor layer, including first and second column regions respectively being of first and second widths; first semiconductor regions provided in the parallel pn structure; second semiconductor regions selectively provided in the first semiconductor regions; a third semiconductor region provided in the parallel pn structure. The third semiconductor region has an end closer to the termination structure portion than a first position, and closer to the active region than a second position. An innermost second column region in the termination structure portion has a column end. The first and second positions are positions at distances equivalent to 50% of first and second widths, from the column end on inner and outer sides thereof, respectively.

### CROSS REFERENCE TO RELATED APPLICATIONS

This application is based upon and claims the benefit of priority of the prior Japanese Patent Application No. 2024-230825, filed on Dec. 26, 2024, the entire contents of which are incorporated herein by reference.

### BACKGROUND OF THE INVENTION

### 1. Field of the Invention

Embodiments of the disclosure relate to a semiconductor device.

### 2. Description of the Related Art

Conventionally, a semiconductor device in which a thickness of a parallel pn layer of an active portion is thinner than a thickness of a pn layer of a voltage withstanding structure portion, and a p⁺-type outer peripheral region is provided between the parallel pn layer of the active portion and a p-type base region is commonly known (for example, refer to Japanese Laid-Open Patent Publication No. 2023-139377).

### SUMMARY OF THE INVENTION

A semiconductor device according to the present disclosure has an active region and a termination structure portion disposed surrounding a periphery of the active region in a top view, the semiconductor device includes: a semiconductor substrate of a first conductivity type, having a front surface and a back surface; a first semiconductor layer of the first conductivity type, provided at the front surface of the semiconductor substrate, the first semiconductor layer having a dopant concentration that is lower than a dopant concentration of the semiconductor substrate; a parallel pn structure provided in the first semiconductor layer, in both the active region and the termination structure portion, the parallel pn structure including a plurality of first column regions of the first conductivity type and a plurality of second column regions of a second conductivity type repeatedly alternating with each other in a direction parallel to the front surface of the semiconductor substrate, each of the plurality of first column regions being of a first width, each of the plurality of second column regions being of a second width; a plurality of first semiconductor regions of the second conductivity type, provided in the parallel pn structure, at a surface thereof, in the active region; a plurality of second semiconductor regions of the first conductivity type, selectively provided in the plurality of first semiconductor regions, at surfaces thereof, in the active region; a plurality of gate electrodes provided, in the active region, via a plurality of gate insulating films that are each in contact with at least one of the plurality of first semiconductor regions and at least one of the plurality of second semiconductor regions; and a third semiconductor region of the second conductivity type, provided in the parallel pn structure, at the surface thereof, in the active region, the third semiconductor region being closer to the termination structure portion than is an outermost gate electrode, which is one of the plurality of gate electrodes that is closest to the termination structure portion. The third semiconductor region has an end facing the termination structure portion, the end being closer to the termination structure portion than is a first position, and being closer to the active region than is a second position. An innermost one of the plurality of second column regions in the termination structure portion has a column end facing the active region. The first position is a position at a distance equivalent to 50% of the first width, from the column end on an inner side thereof, and the second position is a position at a distance equivalent to 50% of the second width from the column end on an outer side thereof.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view of a structure of a silicon carbide semiconductor device according to an embodiment, along cutting line X-X′ depicted in FIG. 3.

FIG. 2 is a cross-sectional view of the structure of the silicon carbide semiconductor device according to the embodiment, along cutting line Y-Y′ depicted in FIG. 3.

FIG. 3 is a top view of the structure of the silicon carbide semiconductor device according to the embodiment.

FIG. 4 is a graph depicting a relationship between a position of the p⁺-type regions of the active region and an edge breakdown voltage in the silicon carbide semiconductor device according to the embodiment.

FIG. 5 is a cross-sectional view depicting the positions of the p⁺-type regions of the active region in the silicon carbide semiconductor device according to the embodiment.

FIG. 6 is a cross-sectional view of a structure of a conventional silicon carbide semiconductor device, along cutting line X-X′ depicted in FIG. 7.

FIG. 7 is a top view of the structure of the conventional silicon carbide semiconductor device.

### DETAILED DESCRIPTION OF THE INVENTION

First, problems associated with the conventional techniques are discussed. In the conventional semiconductor device, a problem occurs in that an end of the p-type region of the active portion is above an n-column of the parallel pn layer, whereby electric field easily concentrates at a corner portion of the p-type region of the active portion, causing decreases in the breakdown voltage.

An outline of an embodiment of the present disclosure is described. A semiconductor device according to the present disclosure solving the problems above and achieving an object has the following features. The semiconductor device has an active region and a termination structure portion disposed outside the active region, surrounding a periphery of the active region. The semiconductor device has: a first semiconductor layer of a first conductivity type, provided at a front surface of a semiconductor substrate of the first conductivity type, the first semiconductor layer having a dopant concentration that is lower than a dopant concentration of the semiconductor substrate; and a parallel pn structure in which a plurality of first column regions of the first conductivity type and a plurality of second column regions of the second conductivity type are provided in the first semiconductor layer repeatedly alternating each other in a direction parallel to the front surface. In the active region, a plurality of first semiconductor regions of a second conductivity type, provided in a surface layer of the parallel pn structure; a plurality of second semiconductor regions of the first conductivity type, selectively provided in a surface layer of the plurality of first semiconductor regions; a plurality of gate electrodes provided, in the active region, via a plurality of gate insulating films that are each in contact with at least one of the plurality of first semiconductor regions and at least one of the plurality of second semiconductor regions; and a third semiconductor region of a second conductivity type, provided in the parallel pn structure, at the surface thereof, in the active region and closer to the termination structure portion than is an outermost one that, of the plurality of gate electrodes, is closest to the termination structure portion, are provided. An end of third semiconductor region, the end facing the termination structure portion, is closer to the termination structure portion than is a position on the active region side, located a distance equivalent to 50% of a width of each of the plurality of first column regions, from a column end of an innermost one of the plurality of second column regions of the termination structure portion, the column end facing the active region, and the end of third semiconductor region is closer to the active region than is a position on the termination structure portion side, located a distance equivalent to 50% of a width of each of the plurality of second column regions, from the column end.

According to the disclosure described, an end of the p⁺-type region (third semiconductor region of the second conductivity type) on the active region side, is closer to the edge termination region than is a position on the active region side, located a distance equivalent to 50% of the width of the n-type region (first column region of the first conductivity type), from the end of the innermost one of the p-type regions (plurality of second column regions of the second conductivity type) of the edge termination region and is closer to the active region than is a position on the edge termination region side, located a distance equivalent to 50% of the width of each of the p-type regions, from the end of the p-type region. As a result, electric field applied to the corner portions of the p⁺-type region is mitigated by the presence of the p-type regions immediately on the outer side (closer the chip end), concentration of the electric field does not easily occur, and the edge breakdown voltage increases. As a result, even in a state where the edge length is shortened and the electric field tends to concentrate more easily, a high edge breakdown voltage may be ensured.

Further, in the semiconductor device according to the present disclosure, in the disclosure above, the end of the third semiconductor region, the end facing the termination structure portion, is closer to the termination structure portion than is a position on the active region side, located a distance equivalent to 30% of the width of each of the plurality of first column regions, from a column end of an innermost one of the plurality of second column regions of the termination structure portion, the column end facing the active region, and the end of third semiconductor region is closer to the active region than is a position on the termination structure portion side, located a distance equivalent to 30% of the width of each of the plurality of second column regions, from the column end.

Further, the semiconductor device according to the present disclosure, in the disclosure above, further includes, in the active region, a plurality of trenches penetrating through the plurality of first semiconductor regions and the plurality of second semiconductor regions and reaching the first semiconductor layer, wherein each of the plurality of gate insulating films is provided in a corresponding one of the plurality of trenches, and each of the plurality of gate electrodes is provided in the corresponding one of the plurality of trenches, via the each of the plurality of gate insulating films.

Further, in the semiconductor device according to the present disclosure, in the disclosure above, the first semiconductor layer has a first surface and a second surface opposite to each other, the second surface facing the semiconductor substrate, and in the termination structure portion, the plurality of first column regions and the plurality of second column regions are not exposed at the first surface of the first semiconductor layer.

Findings underlying the present disclosure are discussed. Conventionally, one commonly known semiconductor device has a super junction (SJ) structure in which the drift layer is a parallel pn layer formed by adjacent n-type regions and p-type regions disposed repeatedly alternating each other in a direction parallel to a main surface of the substrate. The n-type regions and the p-type regions configuring the parallel pn layer extend linearly, parallel to a main surface of a semiconductor substrate (semiconductor chip). The n-type regions and the p-type regions configuring the parallel pn layer are provided substantially uniformly in substantially an entire area of the semiconductor substrate, from the active region of a center (chip center) of the semiconductor substrate to an end of the semiconductor substrate (chip end).

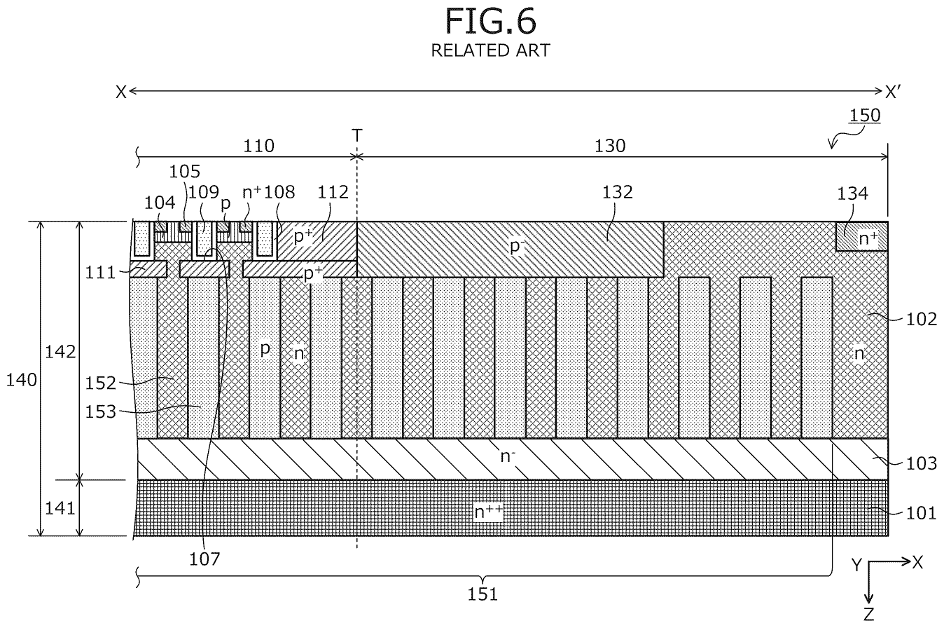

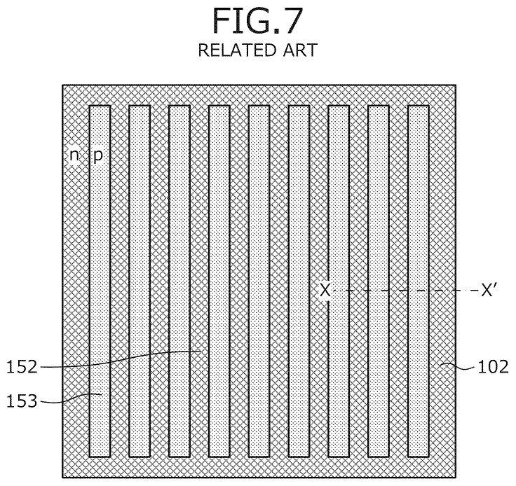

A structure of a conventional silicon carbide semiconductor device having an SJ structure is described taking a metal oxide semiconductor field effect transistor (MOSFET) having insulated gates with a three-layer metal-oxide-semiconductor structure is described as an example. FIG. 6 is a cross-sectional view of the structure of the conventional silicon carbide semiconductor device, along cutting line X-X′ depicted in FIG. 7. FIG. 7 is a top view of the structure of the conventional silicon carbide semiconductor device.

A conventional silicon carbide semiconductor device 150 depicted in FIGS. 6 and 7 has a general trench gate structure in an active region 110 of a semiconductor substrate (semiconductor chip) 140 containing silicon carbide and is a vertical MOSFET having a SJ structure in which an n-type drift layer 102 is a parallel pn layer 151. The semiconductor substrate 140 has a substantially rectangular shape in a plan view. The active region 110 has a substantially rectangular shape in a plan view and is provided in a center (chip center) of the semiconductor substrate 140. A periphery of the active region 110 is surrounded by an edge termination region 130 in a plan view.

The semiconductor substrate 140 is formed by stacking an n-type epitaxial layer 142 constituting an n⁻-type buffer layer 103 and the n-type drift layer 102 on an n⁺⁺-type starting substrate 141 containing silicon carbide. The semiconductor substrate 140 has, as a front surface, a main surface having the n-type epitaxial layer 142 and, as a back surface, a main surface having the n⁺⁺-type starting substrate 141, which constitutes an n⁺⁺-type drain region 101. The n-type epitaxial layer 142 is a portion constituting the n-type drift layer (drift region) 102 and includes the parallel pn layer 151.

Above a front surface of the n⁺⁺-type starting substrate 141 (surface facing the n-type drift layer 102), a MOS gate structure configured by p-type base regions 104, n⁺-type source regions 105, gate trenches 107, gate insulating films 108, and gate electrodes 109 is provided. In the n-type drift layer 102, p⁺-type regions 111 are selectively provided so as to underlie entire bottoms of the gate trenches 107, respectively. In the active region 110, at an outermost of the gate trenches 107 closest to the edge termination region 130, a corresponding one of the p⁺-type regions 111 extends from a sidewall of the outermost one of the gate trenches 107 to a later-described JTE structure 132, the sidewall facing the edge termination region 130. A p⁺-type region 112 is provided on the corresponding one of the p⁺-type regions 111 and is exposed at the surface of the semiconductor substrate 140.

In the edge termination region 130, as a voltage withstanding structure, a junction termination extension (JTE) structure 132 and an n⁺-type channel stopper region 134 are disposed. The JTE structure 132 surrounds the periphery of the active region 110. A boundary T between the active region 110 and the edge termination region 130 is a boundary between an inner peripheral end (inner periphery) of the JTE structure 132 and the p⁺-type regions 111, 112.

The n⁺-type channel stopper region 134 is disposed closer to the chip end than is the JTE structure 132, is apart from the JTE structure 132, and reaches the end of the semiconductor substrate 140. The n⁺-type channel stopper region 134 extends along the end of the semiconductor substrate 140, surrounding a periphery of the JTE structure 132 in a plan view.

The parallel pn layer 151 is provided uniformly in substantially an entire area of the semiconductor substrate 140, from the active region 110 to the edge termination region 130. The parallel pn layer 151 is a SJ structure in which adjacent n-type regions 152 and p-type regions 153 are disposed repeatedly alternating each other in a first direction X that is parallel to the front surface of the semiconductor substrate 140. The n-type regions 152 and the p-type regions 153 of the parallel pn layer 151 extend linearly in a second direction Y that is parallel to the front surface of the semiconductor substrate 140 and orthogonal to the first direction X.

The n-type regions 152 and the p-type regions 153 of the parallel pn layer 151 are disposed in substantially an entire area of the edge termination region 130, from directly below (side facing the n⁺⁺-type drain region 101) the JTE structure 132. The parallel pn layer 151 is in contact with the JTE structure 132 and does not reach the front surface of the semiconductor substrate 140 between the JTE structure 132 and the n⁺-type channel stopper region 134.

The n-type regions 152 and the p-type regions 153 of the parallel pn layer 151 are disposed at equal intervals in substantially an entire area of the semiconductor substrate 140, from the active region 110 to the edge termination region 130. Respective carrier concentrations (dopant concentrations) and widths (widths in the first direction X) of the n-type regions 152 and the p-type regions 153 of the parallel pn layer 151 are set so that the charge of any one of the n-type regions 152 and the charge of an adjacent one of the p-type regions 153 of the parallel pn layer 151 are balanced.

The charge being balanced means that an amount of charge represented by a product of the carrier concentration and the width of one the n-type regions 152 and an amount of charge represented by a product of the carrier concentration and the width of one of the p-type regions 153 are substantially the same within a range that includes an allowable error due to process variation.

As depicted in FIG. 6, in the conventional silicon carbide semiconductor device 150, ends of the p⁺-type regions 111, 112 (at the boundary T between the active region 110 and the edge termination region 130) are positioned directly above a center of one of the n-type regions 152.

In the silicon carbide semiconductor device 150 with the SJ structure, to improve the breakdown voltage and avalanche tolerance, the breakdown voltage of the edge termination region 130 is made higher than the breakdown voltage of the active region 110 and the breakdown voltage of the chip is set to be determined by the breakdown voltage of the cells of the active region 110. Thus, the JTE structure 132, which gradually varies the doping concentration, is formed near the surface of the edge termination region 130, locations where electric field concentrates locally are eliminated, and the electric field is distributed.

However, when the ends of the p⁺-type regions 111, 112 are positioned directly above the center of the n-type region 152, electric field tends to concentrate at corner portions of the p⁺-type regions 111, 112 of the active region 110, which has a relatively high dopant concentration, and a problem arises in that this becomes a rate limiting factor, causing a decrease in the breakdown voltage of the silicon carbide semiconductor device 150 with the SJ structure.

Embodiments of a silicon carbide semiconductor device according to the present disclosure solving the problems of the conventional silicon carbide semiconductor device above are described in detail with reference to the accompanying drawings. In the present description and accompanying drawings, layers and regions prefixed with n or p mean that majority carriers are electrons or holes. Additionally, + or − appended to n or p means that the dopant concentration is higher or lower, respectively, than layers and regions without + or −. In the description of the embodiments below and the accompanying drawings, main portions that are identical are given the same reference numerals and are not repeatedly described. Further, with consideration of variation in manufacturing, description indicating the same or equal may be within 5%.

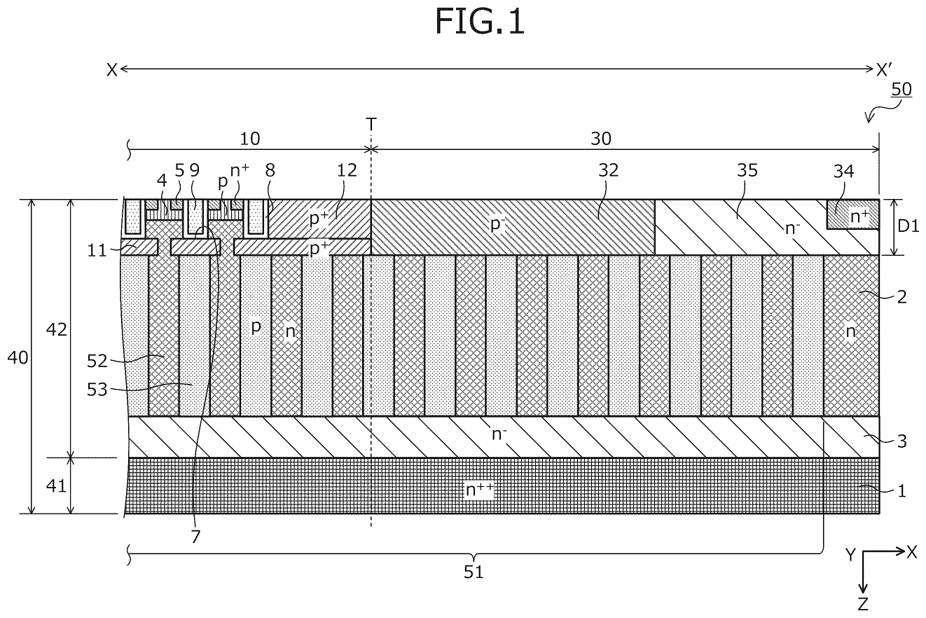

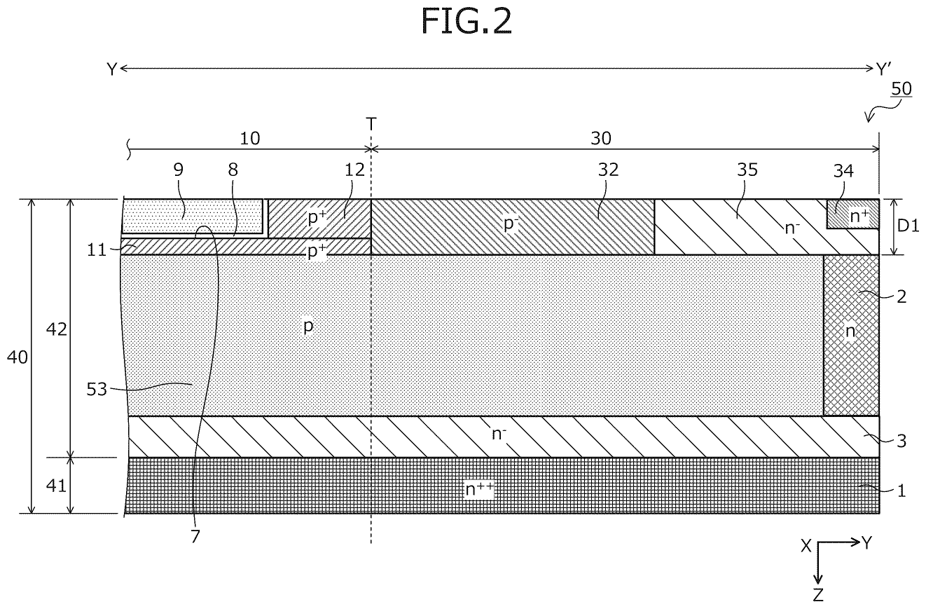

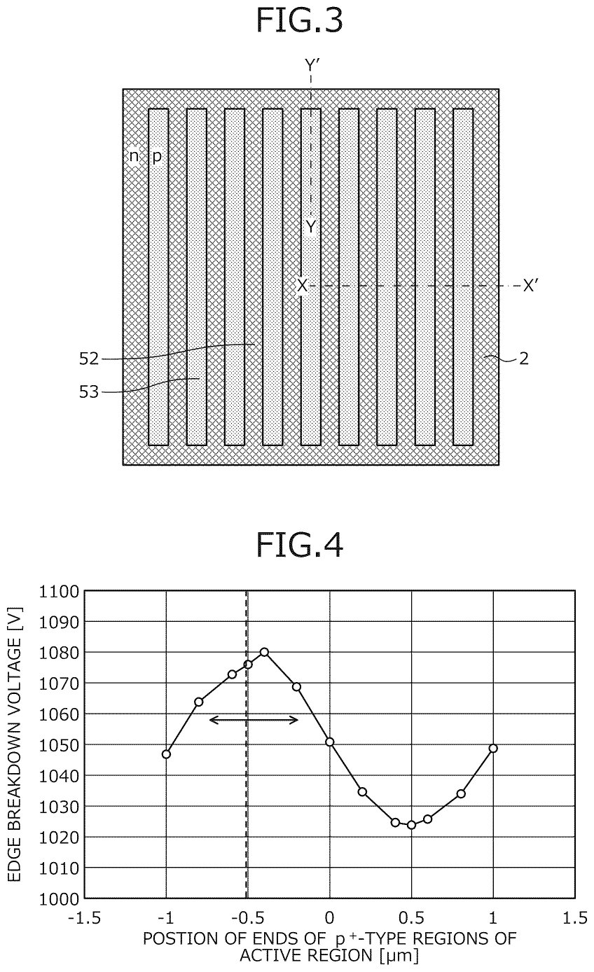

A structure of a silicon carbide semiconductor device according to an embodiment is described taking a MOSFET as an example. FIG. 1 is a cross-sectional view of the structure of the silicon carbide semiconductor device according to the embodiment, along cutting line X-X′ depicted in FIG. 3. FIG. 2 is a cross-sectional view of the structure of the silicon carbide semiconductor device according to the embodiment, along cutting line Y-Y′ depicted in FIG. 3. FIG. 3 is a top view of the structure of the silicon carbide semiconductor device according to the embodiment. In FIG. 3, the number of n-type regions 52 and p-type regions 53 of a parallel pn layer 51 is simplified and scales of FIGS. 1 and 2 differ from each other.

A silicon carbide semiconductor device 50 according to the embodiment has a semiconductor substrate (semiconductor chip) 40 that contains silicon carbide (SiC) and has an active region 10 and an edge termination region (termination structure portion) 30; the silicon carbide semiconductor device 50 is a vertical MOSFET with a trench gate structure (device structure) and a SJ structure in which an n-type drift layer (first semiconductor layer of a first conductivity type) 2 having a dopant concentration not more than 2×10¹⁷/cm³ from the active region 10 to the edge termination region 30 is the parallel pn layer 51. The active region 10 is a region through which a main current flows when the MOSFET is in an on-state and is disposed in a center of the semiconductor substrate 40 (chip center).

The edge termination region 30 is a region between the active region 10 and an end of the semiconductor substrate 40, and surrounds a periphery of the active region 10. The active region 10 and the edge termination region 30 have SJ structures in which the n-type drift layer 2 is configured by the parallel pn layer 51.

The edge termination region 30 has a function of relaxing electric field of a portion of the n-type drift layer 2 in the active region 10 and sustaining a breakdown voltage, said portion facing a front surface (first main surface) of the semiconductor substrate 40. The breakdown voltage is a voltage limit at which leakage current does not increase excessively and no malfunction or destruction of the device occurs. A boundary between the active region 10 and the edge termination region 30 is a boundary between an inner peripheral end (inner periphery) of a later-described JTE structure 32 and later-described p⁺-type regions 11, 12. Near the boundary, the active region 10 has a two-layer structure including one of the p⁺-type regions 11 and the p⁺-type region 12 while the edge termination region 30 has a single layer structure formed by the JTE structure 32.

As depicted in FIGS. 1 and 2, in the silicon carbide semiconductor device 50 according to the embodiment, a general trench gate structure is provided in the semiconductor substrate 40, at the front surface thereof, in the active region 10. The trench gate structure is configured by p-type base regions (first semiconductor regions of a second conductivity type) 4, n⁺-type source regions (second semiconductor regions of the first conductivity type) 5, gate trenches 7, gate insulating films 8, and gate electrodes 9. Further, p⁺⁺-type contact regions (not depicted) may be provided. The semiconductor substrate 40 is formed by stacking on a front surface of an n⁺⁺-type starting substrate (semiconductor substrate of the first conductivity type) 41 containing silicon carbide, an n-type epitaxial layer 42 that constitutes an n⁻-type buffer layer 3 and the n-type drift layer 2.

The semiconductor substrate 40 has, as the front surface, a main surface having the n-type epitaxial layer 42 and, as a back surface (second main surface), a main surface having the n⁺⁺-type starting substrate 41. The n⁺⁺-type starting substrate 41 constitutes an n⁺⁺-type drain region 1 having a dopant concentration of 1×10¹⁸/cm³ or higher. In the embodiment, is a semi-SJ structure in which the n⁻-type buffer layer 3 is provided between the n⁺⁺-type drain region 1 and the parallel pn layer 51. The gate trenches 7 penetrate through the front surface of the semiconductor substrate 40 in a depth direction Z and reach inside the n-type epitaxial layer 42.

The gate trenches 7, for example, extend linearly in a direction parallel to the front surface of the semiconductor substrate 40 (herein, in the second direction Y). In the gate trenches 7, the gate electrodes 9 are provided, via the gate insulating films 8. The p-type base regions 4 extend linearly in the second direction Y between the gate trenches 7 adjacent thereto. The n⁺-type source regions 5 are selectively provided at surfaces of the p-type base regions 4, between the gate trenches 7. The p⁺⁺-type contact regions may be selectively provided at surfaces of the p-type base regions 4, between the gate trenches 7 adjacent thereto.

In the active region 10, the p⁺-type regions 11 are selectively provided between the p-type base regions 4 and the parallel pn layer 51 (the n-type drift layer 2). The p⁺-type regions 11 have a function of relaxing electric field applied to bottoms of the gate trenches 7. The p⁺-type regions 11 are disposed apart from the p-type base regions 4 and face the bottoms of the gate trenches 7 in the depth direction Z, respectively. While not depicted, the p⁺-type regions 11 and the p-type base regions 4 are periodically connected in the second direction Y. In the active region 10, at each of outermost ones of the gate trenches 7 closest to the edge termination region 30, an outermost one of the p⁺-type regions 11 extends to the JTE structure 32, from a sidewall of the each of the outermost ones of the gate trenches, said sidewall facing the edge termination region 30. The p⁺-type region 12 (third semiconductor region of the second conductivity type) is provided in the parallel pn layer 51, at a surface thereof, closer to the edge termination region 30 than is an outermost one of the gate electrodes 8, the p⁺-type region 12 being in contact with the p⁺-type regions 11 and exposed at the surface of the semiconductor substrate 40.

In the edge termination region 30, as a voltage withstanding structure, the junction termination extension (JTE) structure 32 and an n⁺-type channel stopper 34 are disposed. The JTE structure 32 surrounds the periphery of the active region 10 in a plan view. For example, an effective doping concentration of the JTE structure 32 is in a range of 5×10¹⁶ to 5×10¹⁷/cm³ and a length of the JTE structure 32 with an end of the p⁺-type region 11 of the active region 10 as a reference is in a range of 10 μm to 100 μm.

The JTE structure 32 is a structure in which multiple adjacent p-type regions are disposed in descending order of dopant concentration in a direction from the active region 10 to the chip end, in concentric shapes surrounding the periphery of the active region 10 in a plan view. The JTE structure 32 enables relaxation of electric field concentration on the active region side and prevention of device destruction due to application of voltage less than a predetermined voltage (the breakdown voltage of the edge termination region 30).

The n⁺-type channel stopper 34 is disposed apart from the JTE structure 32 and closer to the chip end than is the JTE structure 32, for example, at the four edges (linear portions) of the end of the semiconductor substrate 40, the n⁺-type channel stopper 34 reaches the end of the semiconductor substrate 40. The n⁺-type channel stopper 34 extends along the end of the semiconductor substrate 40 and surrounds the periphery of the JTE structure 32 in a plan view.

The parallel pn layer (parallel pn structure) 51 is a SJ structure in which the n-type regions (first column regions of the first conductivity type) 52 and the p-type regions (second column regions of the second conductivity type) 53 are disposed adjacent to and repeatedly alternating each other in the first direction X parallel to the front surface of the semiconductor substrate 40. The n-type regions 52 and the p-type regions 53 of the parallel pn layer 51 extend linearly to a vicinity of the end of the edge termination region 30, in the second direction Y, which is parallel to the front surface of the semiconductor substrate 40 and orthogonal to the first direction X. Further, the parallel pn layer 51 is disposed in the first direction X, in the active region 10 and the edge termination region 30.

In FIGS. 1 and 2, while the n-type regions 52 and the p-type regions 53 of the parallel pn layer 51 are a semi-SJ structure that does not reach the n⁺⁺-type starting substrate 41, the n-type regions 52 and the p-type regions 53 may constitute a full-SJ structure that reaches the n⁺⁺-type starting substrate 41. Further, lengths of the n-type regions 52 and the p-type regions 53 may be different between the active region 10 and other regions. Further, as depicted in FIG. 1, a pitch of a pair of one of the n-type regions 52 and one of the p-type regions 53 is equal to a pitch of the gate trenches 7 and in the active region 10 in which the gate trenches 7 are formed, the p-type regions 53 are directly below the gate trenches 7. The lengths of the n-type regions 52 and the p-type regions 53 of the parallel pn layer 51 vary depending on the breakdown voltage class and, for example, in a full-SJ structure with a breakdown voltage of 1200 V, the lengths are about 5 μm.

In the parallel pn layer 51, the charge of any one of the n-type regions 52 and the charge of an adjacent one of the p-type regions 53 are roughly balanced. The charge being balanced means that an amount of charge represented by a product of the carrier concentration (dopant concentration) and the width of one of the n-type regions of the parallel pn layer and an amount of charge represented by a product of the carrier concentration and the width of one of the p-type regions are substantially the same within a range that includes an allowable error due to process variation. Accordingly, the respective carrier concentrations and widths (widths in the first direction X) of the n-type regions 52 and the p-type regions 53 are set so that the charge of any one of the n-type regions 52 and an adjacent one of the p-type regions 53 of the parallel pn layer 51 are roughly balanced.

The charge of any one of the n-type regions 52 and an adjacent one of the p-type regions 53 of the parallel pn layer 51 suffice to be roughly balanced and the respective carrier concentrations and widths of the n-type regions 52 and the p-type regions 53 of the parallel pn layer 51 are suitably set. For example, the width of each of the n-type regions 52 of the parallel pn layer 51 and the width of each of the p-type regions 53 may be substantially the same. In this instance, the carrier concentration of the n-type regions 52 and the carrier concentration of the p-type regions 53 may be set to be substantially the same. The widths being substantially the same and the carrier concentrations being substantially the same means that each are within a corresponding range that includes an allowable error due to process variation. For example, the effective doping concentrations of the n-type regions 52 and the p-type regions 53 are in a range of 2×10¹⁶ to 2×10¹⁷/cm³ and the widths are within a range of 0.5 μm to 3 μm. Further, a concentration difference between the n-type regions 52 and the p-type regions 53 is within ±30% and a difference in width between the n-type regions 52 and the p-type regions 53 is within ±20%.

Further, the parallel pn layer 51 is disposed closer to the chip end in the first direction X than is an outer peripheral end (outer periphery) of the JTE structure 32, so that at least one of the p-type regions 53 is disposed closer to the chip end than is the outer peripheral end of the JTE structure 32 in the first direction X.

One or more of the p-type regions 53 of the parallel pn layer 51 is disposed closer to the chip end in the first direction X than is the outer peripheral end of the JTE structure 32, whereby a concentration of electric field at the outer peripheral end of the JTE structure 32 may be suppressed when the MOSFET is off. The outer peripheral end of the JTE structure 32 is an outer peripheral end of an outermost one of the multiple p-type regions configuring the JTE structure 32.

The range in which the parallel pn layer 51 is disposed is set within the above-mentioned range from the outer peripheral end of the JTE structure 32 in the first direction X, and the number of floating p-type regions 53 disposed in the edge termination region 30 is reduced. As a result, the amount of accumulated charge of minority carriers (holes) that accumulate in the edge termination region 30 due to MOSFET switching, etc., and remain without being discharged to the outside may be reduced. Thus, preferably, the number of the p-type regions 53 disposed outside the outer peripheral end of the JTE structure 32 in the first direction X may be small.

Provided that the parallel pn layer 51 is within the above-mentioned range from the outer peripheral end of the JTE structure 32 in the first direction X, the parallel pn layer 51 may be provided in the first direction X, to directly below the n⁺-type channel stopper 34 (the side thereof facing the n⁺⁺-type drain region 1). Between the parallel pn layer 51 and the end of the semiconductor substrate 40 in the first direction X, a normal n-type drift region 2 may be disposed. The size of the semiconductor substrate 40 may be reduced by omitting the normal n-type drift region 2 or by reducing a width of the normal n-type drift region 2.

The n-type regions 52 and the p-type regions 53 of the parallel pn layer 51 of the edge termination region 30 are in contact with the JTE structure 32 in the depth direction Z. The p-type regions 53 of the parallel pn layer 51 provided closer to the chip end than is the JTE structure 32 are provided at positions of a depth D1 from the semiconductor substrate 40 and are not exposed at the surface of the semiconductor substrate 40. The depth D1, for example, is the same as the thickness of the JTE structure 32. Between the surface of the semiconductor substrate 40 and the parallel pn layer 51 provided closer to the chip end than is the JTE structure 32, an n-type layer 35 having a dopant concentration lower than that of the normal n-type drift region 2, for example, a dopant concentration of not more than 2×10¹⁶/cm³, is disposed. As a result, spreading of the depletion layer outward is facilitated.

In the embodiment, in the silicon carbide semiconductor device 50 having the SJ structure, a positional relationship of the ends of the p⁺-type regions 11, 12 of the active region 10 and the p-type regions 53 of the parallel pn layer 51 is defined, whereby the breakdown voltage may be ensured with a short edge length.

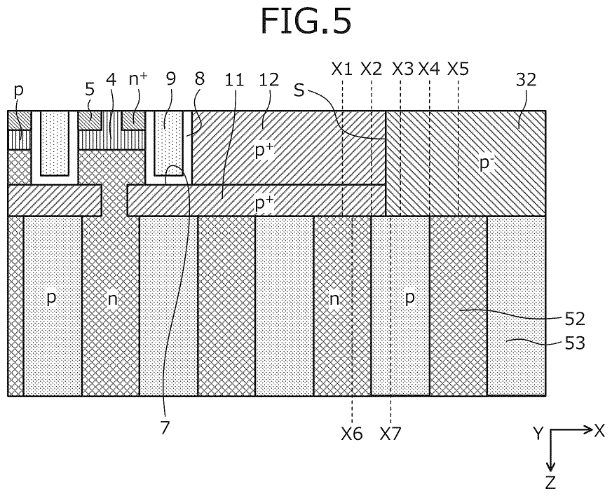

FIG. 4 is a graph depicting a relationship between the position of the p⁺-type regions of the active region and an edge breakdown voltage in the silicon carbide semiconductor device according to the embodiment. FIG. 4 depicts results of simulation of the silicon carbide semiconductor device 50 of a breakdown voltage class of 750 V and having the SJ structure, assuming the silicon carbide semiconductor device 50 with the SJ structure being of a breakdown voltage class of 1200 V to 3300 V. FIG. 5 is a cross-sectional view depicting the positions of the p⁺-type regions of the active region in the silicon carbide semiconductor device according to the embodiment. In FIG. 4, a vertical axis represents the edge breakdown voltage (the breakdown voltage of the edge termination region 30) of the silicon carbide semiconductor device 50 in units of V. A horizontal axis indicates, in units of μm, positions where the ends S of the p⁺-type regions 11, 12 of the active region 10 (refer to FIG. 5) are displaced with respect to a center X3 of the p-type region 53 positioned at the boundary between the active region 10 and the edge termination region 30 (refer to FIG. 5). A positive direction indicates displacement toward the edge termination region 30 while a negative direction indicates displacement toward the active region 10. FIG. 5 depicts an instance in which the ends S of the p⁺-type regions 11, 12 are displaced about −0.25 μm in a negative direction from the center X3 of the p-type region 53.

Further, FIGS. 4 and 5 depict an instance in which the widths of the n-type regions 52 and the p-type regions 53 are each 1 μm. In FIG. 5, X1 (i.e., the first position) corresponds to −1 μm in FIG. 4 in an instance in which the ends S of the p⁺-type regions 11, 12 are positioned above the center of the n-type region 52. In FIG. 5, X2 corresponds to −0.5 μm in FIG. 4 in an instance in which the ends S of the p⁺-type regions 11, 12 are positioned above the boundary between the n-type region 52 and the p-type region 53. In FIG. 5, X3 (i.e., the second position) corresponds to 0 μm in FIG. 4 in an instance in which the ends S of the p⁺-type regions 11, 12 are positioned above the center of the p-type region 53. In FIG. 5, X4 corresponds to 0.5 μm in FIG. 4 in an instance in which the ends S of the p⁺-type regions 11, 12 are positioned above the boundary between the p-type region 53 and the n-type region 52. In FIG. 5, X5 corresponds to 1 μm in FIG. 4 in an instance in which the ends S of the p⁺-type regions 11, 12 are positioned above the center of the n-type region 52. Further, in the conventional silicon carbide semiconductor device 150 depicted in FIG. 6, an instance in which ends S of the p⁺-type regions 111, 112 are positioned above the center of the n-type region 152 corresponds to X5 in FIG. 5.

As depicted in FIG. 4, in an instance in which the ends S of the p⁺-type regions 11, 12 are displaced −1 μm to 0 μm from the center X3 of the p-type region 53, the edge breakdown voltage increases and in an instance in which the ends S of the p⁺-type regions 11, 12 are displaced 0 μm to 1 μm from the center X3 of the p-type region 53, the edge breakdown voltage decreases.

FIG. 4 corresponds to an instance in which widths of the n-type region 52 and the p-type region 53 are each 1 μm and thus, in the embodiment, the ends S of the p⁺-type regions 11, 12 of the active region 10 are closer to the edge termination region 30 than is a position X1 on the active region 10 side, located a distance equivalent to 50% of the width of the n-type region 52, from an end X2 of an innermost one (the one closest to the active region 10) of the p-type regions 53 of the edge termination region 30 and are closer to the active region 10 than is a position X3 on the edge termination region 30 side, located a distance equivalent to 50% of the width of the p-type region 53, from the end X2. In other words, the ends S are between the position X1 and the position X3 and exclude the position X1 and the position X3. As a result, the edge breakdown voltage of the silicon carbide semiconductor device 50 may be increased (in the example depicted in FIG. 4, about 1050 V or higher). Furthermore, the ends S of the p⁺-type regions 11, 12 on the active region 10 side are closer to the edge termination region 30 than is a position X6 (i.e., the third position, refer to FIG. 5) on the active region 10 side, located a distance equivalent to 30% of the width of the n-type region 52, from the end X2 of the p-type region 53 and are closer to the active region 10 than is a position X7 (i.e., the fourth position, refer to FIG. 5) on the edge termination region 30 side, located a distance equivalent to 30% of the width of the p-type region 53, from the end X2, whereby the edge breakdown voltage of the silicon carbide semiconductor device 50 may be further increased (in the example depicted in FIG. 4, about 1060 V or higher). In this instance, the ends S are between the position X6 and the position X7 and exclude the position X6 and the position X7.

Further, the p-type region 53 located at the boundary between the active region 10 and the edge termination region 30 defines the ends S of the p⁺-type regions 11, 12 of the active region 10 and, preferably, may be, as counted from the inner side (the active region 10 side), a first to a fiftieth one of the p-type regions 53 that are closer to the chip end than is an outermost one of the gate trenches 7.

As described, when the position of the ends S of the p⁺-type regions 11, 12 is within the range described above, while electric field is applied to the corner portions of the p⁺-type regions 11, 12, the electric field is relaxed by the extension of the p-type region 53 immediately on the outer side (side facing the edge termination region 30) thereof, whereby concentration of the electric field does not easily occur and the edge breakdown voltage increases. As a result, even in state in which an edge length (length of the edge termination region) is shortened and electric field tends to concentrate more, a high edge breakdown voltage may be ensured. Thus, in the silicon carbide semiconductor device 50 of the embodiment, the edge length necessary for ensuring the breakdown voltage may be reduced. In particular, this is effective in an instance in which the edge length of the silicon carbide semiconductor device 50 is reduced (for example, when the length of the JTE structure 32 is 10 μm).

Next, a method of manufacturing the silicon carbide semiconductor device 50 according to the embodiment is described. First, at the front surface of the n⁺⁺-type starting substrate (semiconductor wafer) 41 constituting the n⁺⁺-type drain region 1, the n-type drift layer 2 and the n⁻-type buffer layer 3 including the parallel pn layer 51 are formed. For example, in an instance in which a multistage epitaxial method is used, the n-type epitaxial layer 42 constituting the n⁻-type buffer layer 3 and the n-type drift layer 2 is divided into multiple stages (for example, 9 stages) and regions constituting the n-type regions 52 and the p-type regions 53 are selectively formed by ion implantation in each stage of epitaxial growth so that conductive regions of the same conductivity type are adjacent to each other in the depth direction Z in the n-type epitaxial layer 42.

Further, for example, after the n-type epitaxial layer 42 constituting the n⁻-type buffer layer 3 and the n-type drift layer 2 is formed, the parallel pn layer 51 may be formed by forming trenches (hereinafter, SJ trenches) in the n-type epitaxial layer 42, leaving portions constituting the n-type regions 52, and embedding, in the SJ trenches, a p-type epitaxial layer constituting the p-type regions 53 using a trench embedding epitaxial method.

Further, the p⁺-type regions 11, 12, the n⁺-type source regions 5, the p⁺⁺-type contact regions, the JTE structure 32, the n⁺-type channel stopper 34, and the n⁻-type layer 35 may be formed by ion implantation. Thereafter, the gate trenches 7 are formed and the gate insulating films 8 are formed along the front surface of the semiconductor substrate 40 and inner walls of the gate trenches 7. At this time, in the embodiment, the p⁺-type regions 11, 12 are formed so that, for example, the ends S of the p⁺-type regions 11, 12 on the active region 10 side are closer to the edge termination region 30 than is the position X1 on the active region 10 side, located a distance equivalent to 50% of the width of the n-type region 52, from the end X2 of the innermost one of the p-type regions 53 of the edge termination region 30 and are formed to be closer to the active region 10 than is the position X3 on the edge termination region 30 side, located a distance equivalent to 50% of the width of the p-type region 53, from the end X2. Preferably, the ends S of the p⁺-type regions 11, 12 on the active region 10 side are closer to the edge termination region 30 than is the position X6 on the active region 10, located a distance equivalent to 30% of the width of the n-type region 52, from the end X2 of the p-type region 53 and closer to the active region 10 than is the position X7 on the edge termination region 30 side, located a distance equivalent to 30% of the width of the p-type region 53 from the end X2. Next, a polysilicon layer is deposited on the front surface of the semiconductor substrate 40 so as to be embedded in the gate trenches 7 and etched, leaving portions thereof constituting the gate electrodes 9 in the gate trenches 7. Thus, the silicon carbide semiconductor device 50 depicted in FIGS. 1 and 2 may be formed.

As described above, according to the embodiment, an end of the p⁺-type region, said end on the active region side thereof, is closer to the edge termination region than is a position on the active region side, located a distance equivalent to 50% of the width of the n-type region, from the end of the innermost p-type region of the edge termination region and is closer to the active region than is a position on the edge termination region side, located a distance equivalent to 50% of the width of the p-type region, from said end of the p-type region. As a result, electric field applied to corner portions of the p⁺-type region is mitigated by the presence of the p-type regions immediately on the outer side (closer the chip end), concentration of the electric field does not easily occur, and the edge breakdown voltage increases. As a result, even in a state where the edge length is shortened and the electric field tends to concentrate more easily, a high edge breakdown voltage may be ensured.

In the foregoing, while in the present disclosure, an instance in which a MOS gate structure is configured in the silicon carbide substrate, at the first main surface thereof is described as an example, without limitation hereto, various modifications are possible, such as with the orientation of the main surface of the substrate. Further, in the embodiments of the present disclosure, while a trench-type MOSFET is described as an example, without limitation hereto, the present disclosure is applicable to semiconductor devices of various types of configuration such as MOS-type semiconductor devices like trench-type IGBTs. Further, in the embodiments described above, while an instance in which silicon carbide is used as a semiconductor is described as an example, other than silicon carbide, for example, a semiconductor such as (Si), gallium nitride (GaN), or the like may be used. Further, in the present disclosure, in the embodiments, while the first conductivity type is assumed to be an n-type and the second conductivity type is assumed to be a p-type, the present disclosure is similarly implemented when the first conductivity type is a p-type and the second conductivity type is an n-type.

According to the disclosure described, an end of the p⁺-type region (third semiconductor region of the second conductivity type) on the active region side, is closer to the edge termination region than is a position on the active region side, located a distance equivalent to 50% of the width of the n-type region (first column region of the first conductivity type), from the end of the innermost one of the p-type regions (plurality of second column regions of the second conductivity type) of the edge termination region and is closer to the active region than is a position on the edge termination region side, located a distance equivalent to 50% of the width of each of the p-type regions, from the end of the p-type region. As a result, electric field applied to the corner portions of the p⁺-type region is mitigated by the presence of the p-type regions immediately on the outer side (closer the chip end), concentration of the electric field does not easily occur, and the edge breakdown voltage increases. As a result, even in a state where the edge length is shortened and the electric field tends to concentrate more easily, a high edge breakdown voltage may be ensured.

The semiconductor device according to the present disclosure achieves an effect in that concentration of electric field at the end of the p-type region of the active portion is mitigated and a high breakdown voltage may be realized.

As described, the silicon carbide semiconductor device according to the present disclosure is useful for high voltage semiconductor devices such as those used in power converting equipment, power source devices of, for example, various types of industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device having an active region and a termination structure portion disposed surrounding a periphery of the active region in a top view, the semiconductor device comprising:
a semiconductor substrate of a first conductivity type, having a front surface and a back surface;
a first semiconductor layer of the first conductivity type, provided at the front surface of the semiconductor substrate, the first semiconductor layer having a dopant concentration that is lower than a dopant concentration of the semiconductor substrate;
a parallel pn structure provided in the first semiconductor layer, in both the active region and the termination structure portion, the parallel pn structure including a plurality of first column regions of the first conductivity type and a plurality of second column regions of a second conductivity type repeatedly alternating with each other in a direction parallel to the front surface of the semiconductor substrate, each of the plurality of first column regions being of a first width, each of the plurality of second column regions being of a second width;
a plurality of first semiconductor regions of the second conductivity type, provided in the parallel pn structure, at a surface thereof, in the active region;
a plurality of second semiconductor regions of the first conductivity type, selectively provided in the plurality of first semiconductor regions, at surfaces thereof, in the active region;
a plurality of gate electrodes provided, in the active region, via a plurality of gate insulating films that are each in contact with at least one of the plurality of first semiconductor regions and at least one of the plurality of second semiconductor regions; and
a third semiconductor region of the second conductivity type, provided in the parallel pn structure, at the surface thereof, in the active region, the third semiconductor region being closer to the termination structure portion than is an outermost gate electrode, which is one of the plurality of gate electrodes that is closest to the termination structure portion, wherein
the third semiconductor region has an end facing the termination structure portion, the end being closer to the termination structure portion than is a first position, and being closer to the active region than is a second position, wherein
an innermost one of the plurality of second column regions in the termination structure portion has a column end facing the active region,
the first position is a position at a distance equivalent to 50% of the first width, from the column end on an inner side thereof, and
the second position is a position at a distance equivalent to 50% of the second width from the column end on an outer side thereof.

2. The semiconductor device according to claim 1, wherein
said end of the third semiconductor region is closer to the termination structure portion than is a third position, and is closer to the active region than is a fourth position, wherein
the third position is a position at a distance equivalent to 30% of the first width from the column end on the inner side thereof, and
the fourth position is a position, at a distance equivalent to 30% of the second width from the column end on the outer side thereof.

3. The semiconductor device according to claim 1, further comprising, in the active region, a plurality of trenches penetrating through the plurality of first semiconductor regions and the plurality of second semiconductor regions and reaching the first semiconductor layer, wherein
the plurality of gate insulating films are provided respectively in the plurality of trenches, and
the plurality of gate electrodes are provided in the plurality of trenches, via the plurality of gate insulating films, respectively.

4. The semiconductor device according to claim 1, wherein
the first semiconductor layer has a first surface and a second surface opposite each other, the second surface facing the semiconductor substrate, and
in the termination structure portion, the plurality of first column regions and the plurality of second column regions are not exposed at the first surface of the first semiconductor layer.
